(19) United States
(12) Patent Application Publication
(10) Pub. No.: US 2012/0061640 A1
(43) Pub. Date: Mar. 15, 2012

(54) SEMICONDUCTOR LIGHT EMITTING DEVICE

(75) Inventors: Ryota Kitagawa, Tokyo (JP); Akira Fujimoto, Kanagawa-ken (JP); Koji Asakawa, Kanagawa-ken (JP); Takanobu Kamakura, Kanagawa-ken (JP); Shinji Nunotani, Tokyo (JP); Masaaki Ogawa, Kanagawa-ken (JP)

(73) Assignee: Kabushiki Kaisha Toshiba, Tokyo (JP)

(21) Appl. No.: 13/037,864

(22) Filed: Mar. 1, 2011

(30) Foreign Application Priority Data
Sep. 9, 2010 (JP) 2010-202460

(51) Int. Cl. H01L 33/06

(52) U.S. Cl. 257/13; 257/E33.008

(57) ABSTRACT

A semiconductor light emitting device includes a first semiconductor layer of a first conductivity type, a first electrode layer, a second semiconductor layer of a second conductivity type, a light emitting layer and a second electrode layer. The first electrode layer includes a metal portion having a plurality of opening portions. The opening portions have an equivalent circle diameter being not less than 10 nanometers and not more than 50 micrometers. The second semiconductor layer is provided between the first semiconductor layer and the first electrode layer and includes a first portion in contact with the first electrode layer. The first portion has an impurity concentration of not less than 1×10¹⁹/cubic centimeter and not more than 1×10²¹/cubic centimeter. The light emitting layer is provided between the first semiconductor layer and the second semiconductor layer. The second electrode layer is connected to the first semiconductor layer.

### CROSS-REFERENCE TO RELATED APPLICATION

This application is based upon and claims the benefit of priority from the prior Japanese Patent Application No. 2010-202460, filed on Sep. 9, 2010; the entire contents of which are incorporated herein by reference.

### FIELD

Embodiments described herein relate generally to a semiconductor light emitting device.

### BACKGROUND

Semiconductor light emitting devices are provided with an electrode in ohmic contact with a face of a semiconductor layer. A semiconductor light emitting device can be made to emit light by supplying a current flowing through the electrode. For lighting apparatuses and the like, a comparatively large light emitting device is desired. Therefore a semiconductor light emitting device may includes a fine wire electrode extending from a pad electrode along the surface of the semiconductor. Also, a semiconductor light emitting device may include a metal electrode provided on the whole light emitting surface, and fine opening portions are formed on the metal electrode. In these semiconductor light emitting devices further improvement of the properties is required.

### BRIEF DESCRIPTION OF THE DRAWINGS

FIG. 1 is a schematic perspective view illustrating a semiconductor light emitting device;

FIGS. 2A to 2C are schematic plan views illustrating the shapes of opening portions;

FIG. 3 is a graph illustrating relationships between a concentration of dopants and resistance values;

FIG. 4 is a flowchart illustrating a method of manufacturing the semiconductor light emitting device;

FIGS. 5A to 5E are schematic cross-sectional views illustrating a manufacturing method of the semiconductor light emitting device according to first to third examples;

FIGS. 6A to 6F are schematic cross-sectional views illustrating a manufacturing method of the semiconductor light emitting device according to a fourth example;

FIGS. 7A to 7I are schematic cross-sectional views illustrating a manufacturing method of the semiconductor light emitting device according to a fifth example;

FIGS. 8A to 8F are electron microscope photographs showing plan views of first electrode layers of the semiconductor light emitting devices;

FIG. 9 is a table showing the equivalent circle diameter of the opening portions, average distance between the opening portions, and the opening portion area ratio in the plan view of the semiconductor light emitting device according to each example;

FIG. 10 is a graph illustrating examples of the properties of the semiconductor light emitting devices; and

FIGS. 11A to 11F is a schematic cross-sectional view illustrating a manufacturing method of the semiconductor light emitting device according to a seventh example.

### DETAILED DESCRIPTION

In general, according to one embodiment, a semiconductor light emitting device includes a first semiconductor layer of a first conductivity type, a first electrode layer, a second semiconductor layer of a second conductivity type, a light emitting layer and a second electrode layer. The first electrode layer includes a metal portion having a plurality of opening portions. The plurality of opening portions penetrate the metal portion along a direction from the first semiconductor layer toward the first electrode layer. The plurality of opening portions have an equivalent circle diameter of a shape of the plurality of opening portions when viewed along the direction. The equivalent circle diameter is not less than 10 nanometers and not more than 50 micrometers. The second semiconductor layer of a second conductivity type is provided between the first semiconductor layer and the first electrode layer. The second semiconductor layer includes a first portion in contact with the first electrode layer. The first portion has an impurity concentration of not less than 1×10¹⁹/cubic centimeter and not more than 1×10²¹/cubic centimeter. The light emitting layer is provided between the first semiconductor layer and the second semiconductor layer. The second electrode layer is connected to the first semiconductor layer.

Embodiments of the invention will now be described with reference to the drawings.

Note that the drawings are schematic or simplified illustrations and that relationships between thicknesses and widths of parts and proportions in size between parts may differ from actual parts. Also, even where identical parts are depicted, mutual dimensions and proportions may be illustrated differently depending on the drawing.

Note that in the drawings and specification of this application, the same numerals are applied to constituents that have already appeared in the drawings and have been described, and repetitious detailed descriptions of such constituents are omitted.

Also, in the following explanation, examples are given as examples wherein a first conductivity type is n-type, and a second conductivity type is p-type.

### First Embodiment

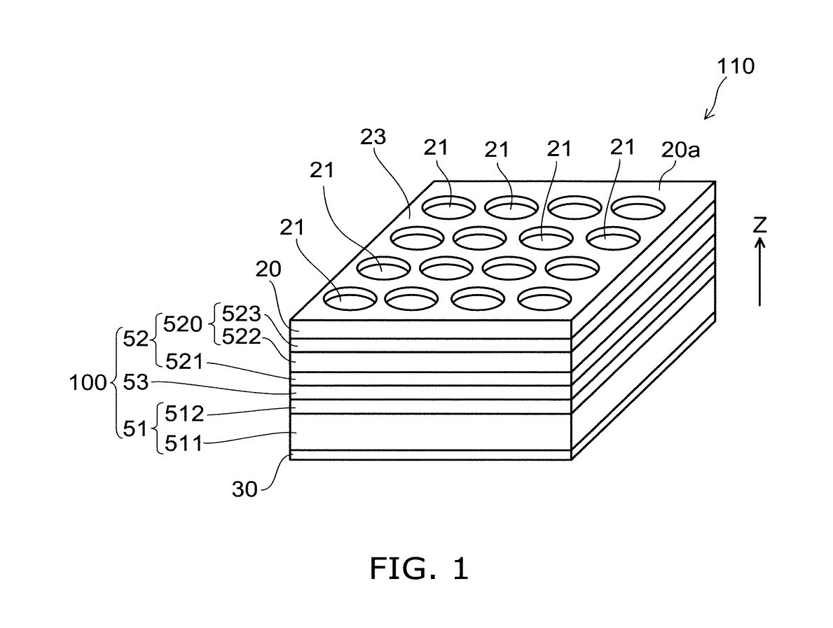

FIG. 1 is a schematic perspective view illustrating a configuration of a semiconductor light emitting device according to a first embodiment.

A semiconductor light emitting device 110 according to the first embodiment includes a structural body 100, a first electrode layer 20, and a second electrode layer 30.

The structural body 100 includes a first semiconductor layer 51 of a first conductivity type, a second semiconductor layer 52 of a second conductivity type, and a light emitting layer 53 provided between the first semiconductor layer 51 and the second semiconductor layer 52.

The first semiconductor layer 51 includes a clad layer 512 made of, for example, n-type InAlP. The clad layer 512 is formed on a substrate 511 of, for example, n-type GaAs. In the embodiment, for convenience the substrate 511 is included in the first semiconductor layer 51.

The second semiconductor layer 52 is provided between the first semiconductor layer 51 and the first electrode layer 20. The second semiconductor layer 52 includes a clad layer 521 made of, for example, p-type InAlP. The second semiconductor layer 52 includes a first portion 520 in contact with the first electrode layer 20. The first portion 520 is provided on the clad layer 521. A current diffusion layer 522 made of, for example, p-type InGaAlP is provided in the first portion 520. The first portion 520 may also include a contact layer 523 in contact with the first electrode layer 20.

The light emitting layer 53 is provided between the first semiconductor layer 51 and the first electrode layer 20. Specifically, the light emitting layer 53 is provided between the first semiconductor layer 51 and the second semiconductor layer 52. In the semiconductor light emitting device 110, a heterostructure is constituted by, for example, the clad layer 512 of the first semiconductor layer 51, the light emitting layer 53, and the clad layer 521 of the second semiconductor layer 52.

The first electrode layer 20 is provided on the side of the second semiconductor layer 52 that is opposite the first semiconductor layer 51. The first electrode layer 20 includes, for example Au and Ag, or Au and Ag which contains impurities, as described later.

In the embodiment, for convenience of explanation, the second semiconductor layer 52 side of the structural body 100 is defined as the front side or top side, and the first semiconductor layer 51 side of the structural body 100 is defined as the reverse side or bottom side. Also, a direction from the first semiconductor layer 51 toward the second semiconductor layer 52 along a stacking direction is defined as a “Z-axis direction”.

The first electrode layer 20 includes a metal portion 23 and a plurality of opening portions 21. The plurality of opening portions 21 penetrate the metal portion 23 along the Z-axis direction. Equivalent circle diameters of the plurality of opening portions 21 are more than or equal to 10 nm and less than or equal to 50 μm.

Here, the equivalent circle diameter is defined by the following equation (1).

Equivalent circle diameter=2×(Area/π)^{1/2} (1)

Here, “Area” in the above equation is an area of the opening portion 21 when viewed from the Z-axis direction.

The opening portion 21 is not necessarily circular shaped. Therefore in the embodiment, the opening portion 21 can be specified using the definition of the equivalent circle diameter.

The second electrode layer 30 has electrical continuity with the first semiconductor layer 51. In this example, the second electrode layer 30 is provided on the reverse side of the structural body 100. Au—Ge alloy, for example, can be used for the second electrode layer 30.

In this type of semiconductor light emitting device 110, a face on which the first electrode layer 20 is formed is mainly used as the light emitting face. In other words, by applying a predetermined voltage between the first electrode layer 20 and the second electrode layer 30, light having a predetermined central wavelength is emitted from the light emitting layer 53. This light is mainly extracted to the outside from a major surface 20a of the first electrode layer 20.

In the semiconductor light emitting device 110 according to the first embodiment, an impurity concentration in the first portion 520 is more than or equal to 1×10¹⁹/cubic centimeter (cm⁻³) and less than or equal to 1×10²¹ cm⁻³. The plurality of opening portions 21 are provided in the first electrode layer 20. Then, it is possible to efficiently emit the light to the outside while maintaining a spread of current to the light emitting layer 53 from the first electrode layer 20, which includes opening portions 21 having a size more than or equal to 10 nm and less than or equal to 50 μm, for example. In other words, according to the semiconductor light emitting device 110, a luminous efficiency of the light emitting layer 53 is improved, and it is possible to increase a light extraction efficiency the first electrode layer 20.

Next, an example of the semiconductor light emitting device 110 is described.

The semiconductor light emitting device 110 includes, for example, an n-type GaAs substrate 511, and a heterostructure that includes, for example, an n-type InAlP clad layer 512, an InGaAlP light emitting layer 53, and a p-type InAlP clad layer 521 is formed on the substrate 511.

The light emitting layer 53 may include, for example, a multiple quantum well (MQW) which contains barrier layers and well layers alternately provided. Also, the light emitting layer may include a single quantum well (SQW) which contains one well layer sandwiched by a pair of the barrier layers.

Moreover, a current diffusion layer 522 made of, for example, p-type InGaAlP is formed on the light emitting layer 53. A role of the current diffusion layer 522 is to diffuse a current along directions normal to the Z-axis direction.

The current diffusion layer 522 may be doped with carbon, zinc (Zn), magnesium (Mg), or the like. Thereby, a resistance value of the current diffusion layer 522 decreases and current can be spread easily in the current diffusion layer 522.

A contact layer 523 made of, for example, GaAs is formed on the current diffusion layer 522, and the first electrode layer 20 is formed via the contact layer 523. Thereby, the contact layer 523 can be considered part of the first portion 520 of the second semiconductor layer 52 according to the first embodiment.

Here, GaAs and GaP for example, may be used for the contact layer 523. However the embodiment is not limited to this. In other words, the material used for the contact layer 523 may be appropriately selected based on, for example, materials used in the current diffusion layer 522 which is adjacent to the contact layer 523, and the materials used for the first electrode layer 20.

The sheet resistance value of the contact layer 523 is less than, for example, 10³ ohms (Ω)/square. Thereby, it is possible to form ohmic contact with the first electrode 20 easily. Also, a uniform current spreading can be obtained, and an increase in brightness is more distinct.

Note that the configuration of these semiconductor layers is an example, but the embodiment is not limited to this configuration.

The first electrode layer 20 includes a stacked structure, for example, Au and Au—Zn alloy, as a p-side electrode. The plurality of opening portions 21 are provided in the first electrode layer 20 penetrating the metal portion 23 along the Z-axis direction. The size and arrangement of the opening portions 21 may be regular or may be irregular.

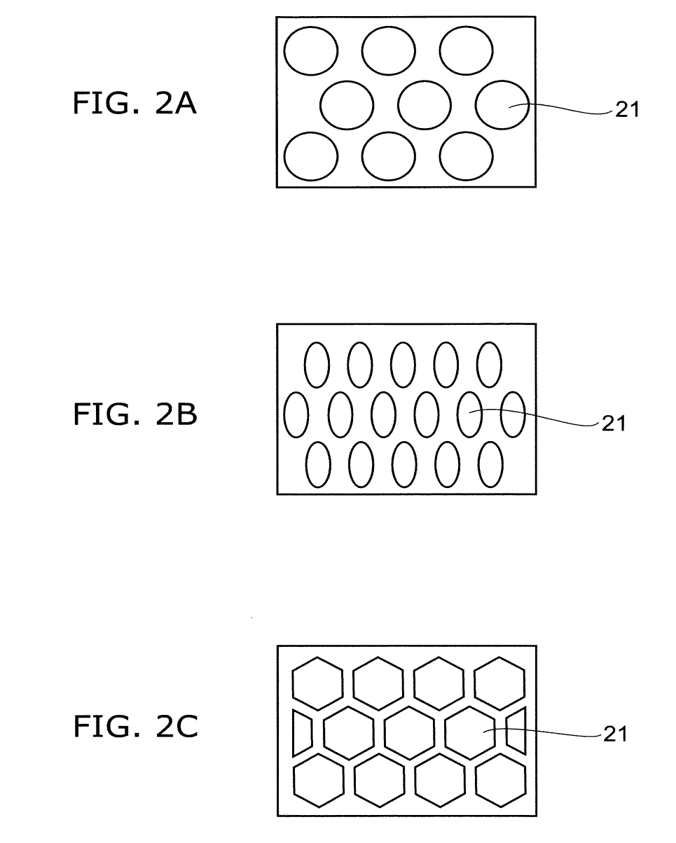

FIGS. 2A to 2C are schematic plan views illustrating examples of the shapes of the opening portions 21.

In FIGS. 2A to 2C, the shapes of the opening portions 21 are illustrated as viewed from the Z-axis direction.

Shapes of the opening portions 21 illustrated in FIG. 2A are roughly circular. Also, shapes of the opening portions 21 illustrated in FIG. 2B are roughly elliptical. Also, shapes of the opening portions 21 illustrated in FIG. 2C are roughly hexagonal, and if used in the first semiconductor layer 20, a plurality of roughly hexagonal opening portions 21 are arranged in a honeycomb manner.

These opening portion shapes are examples, and the embodiment is not limited to these shapes. Also, the opening portion shapes may be a combination of various shapes.

In the following explanation, the case that the shape of the opening portions 21 is roughly circular is taken as an example.

As illustrated in FIG. 1, the n-side second electrode layer 30 that includes, for example, Au—Ge alloy is formed on the reverse face of the structural body 100. The second electrode layer 30 forms ohmic contact and has electrical continuity with the first semiconductor layer 51.

In the semiconductor light emitting device 110 according to the embodiment, the light emitted from the light emitting layer 53 is emitted to the outside from the face of the second semiconductor layer 52, which is a current diffusion layer, on which the first electrode layer 20 is provided.

This type of semiconductor light emitting device 110 is used in various types of apparatus. To date, the use of the semiconductor light emitting device 110 in image display devices and lighting devices has been investigated. This semiconductor light emitting device 110 is basically provided with electrodes on the two faces of the semiconductor layers, and emits light by supplying current that flows between the electrodes.

In a typical semiconductor light emitting device, current flows through a pad electrode provided on a portion of the top face of the semiconductor layer, and light is emitted from around the pad electrode.

In the semiconductor light emitting device, it may be preferable to make a light emitting region larger. For example, a device of adding a fine wire electrode extending from the pad electrode along the top face of the semiconductor layer can be implemented to increase an area of the light emitting portion by spreading out the current. However, if the fine wire electrode is made too large, the electrode structure becomes complex. Also, if the area of the electrode is increased, the area of the face from which the light is extracted decreases, so sufficient brightness is not obtained.

On the other hand, brightness properties of the semiconductor light emitting device with respect to a current have a peak at a certain current value, and the brightness is reduced if the current increases over the value corresponding to the peak brightness.

One of the causes of the reduction in the brightness is insufficient dissipation of the heat generated within the semiconductor light emitting device due to the excess current flowing. Therefore, to achieve a high brightness semiconductor light emitting device, it may be preferable to sufficiently cool the semiconductor light emitting device. In other words, it may be preferable to improve the heat dissipation.

In the semiconductor light emitting device 110 according to the embodiment, the first electrode layer 20 includes a metal portion 23 penetrated by the plurality of opening portions 21. The first electrode layer 20 having the opening portions 21 in this way is made of metal, so compared with a semiconductor that normally constitutes the current diffusion layer or oxide transparent electrodes such as Indium Tin Oxide (ITO) or the like, an electrical conductivity is one or two orders of magnitude larger, and a thermal conductivity is also high. Therefore, when combined to form the semiconductor light emitting device 110, a forward direction voltage (Vf) becomes lower and the heat dissipation is improved, compared with the case in which ITO is used. As a result, a current concentration which is induced only in a portion of the light emitting layer 53 is mitigated. Therefore, a light is emitted more uniformly over the whole light emitting layer 53, and the brightness increases.

In the semiconductor light emitting device 110 according to the embodiment, the first electrode layer 20 may include the opening portions 21 that are larger than the wavelength of the light generated in the light emitting layer 53, and it is possible to suppress the current concentration and the reduction in brightness, by controlling a doping concentration of the first portion 520 of the second semiconductor layer 52.

In the semiconductor light emitting device 110, (1) an impurity concentration in the first portion 520 of the second semiconductor layer 52 may be more than or equal to 1×10¹⁹ cm⁻³ and less than or equal to 1×10²¹ cm⁻³ or lower, and (2) an equivalent circle diameter of the opening portions 21 of the first electrode layer 20 may be more than or equal to 10 nm and less than or equal to 50 μm. Also, (3) a thickness of the first electrode layer 20 may preferably be more than or equal to 10 nm and less than or equal to 100 nm.

The property_(1) mentioned above is based on results of a simulation of the impurity concentration in the first portion 520 of the second semiconductor layer 52.

In other words, in the semiconductor light emitting device 110, by making the impurity concentration of the first portion 520 more than or equal to 1×10¹⁹ cm⁻³ and less than or equal to 1×10²¹ cm⁻³, it may be possible to increase the brightness even if the equivalent circle diameters of the opening portions 21 are relatively large.

According to the property (1), it may also be possible to increase the brightness in the semiconductor light emitting device 110 that includes the first electrode layer 20 having the plurality of opening portions 21. Furthermore, in the semiconductor light emitting device 110, it may be possible to increase the brightness in the region where the higher current is supplied.

Also, the brightness can be improved even with opening portions 21 with equivalent circle diameters that can be formed by photolithography.

In the semiconductor light emitting device 110, the resistance value (i.e., impurity concentration) of the first portion 520 of the second semiconductor layer 52 on the lower side of the first electrode layer 20 is preferably adjusted. The current injected from the first electrode layer 20 spreads within the second semiconductor layer 52 and reaches the light emitting layer 53. At this time the distance over which the current spreads is proportional to the resistance value of the second semiconductor layer 52 to the power of −½. In other words, the smaller the resistance value of the second semiconductor layer 52 the easier it is for the current to spread. Thereby, a uniform light emission can be obtained in the whole semiconductor light emitting device 110.

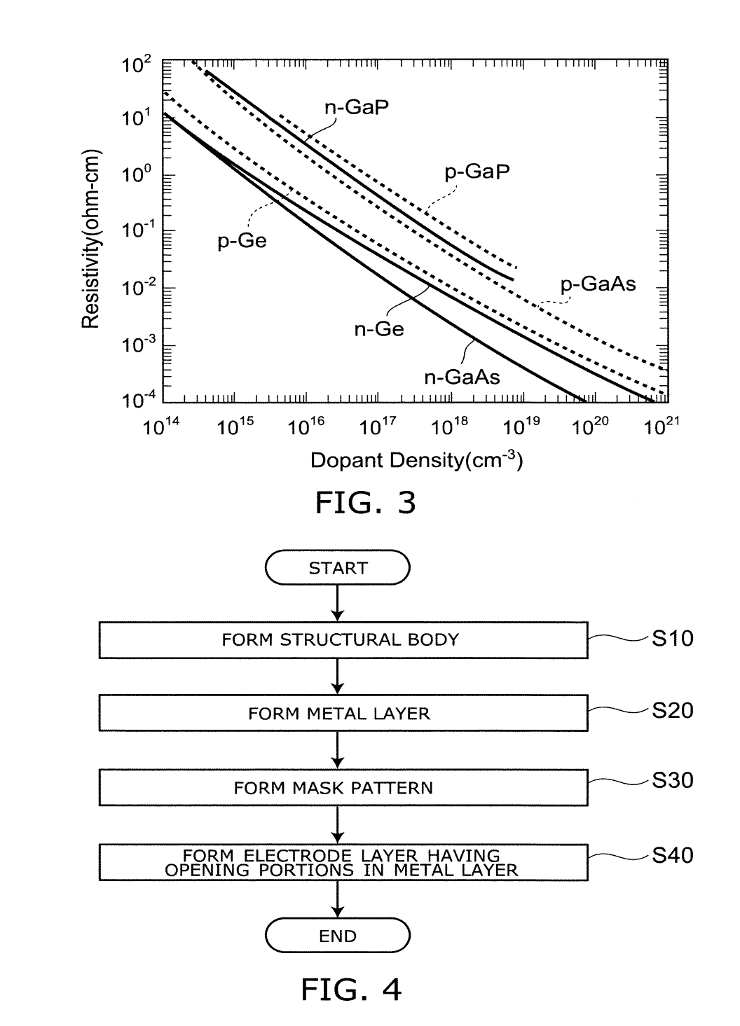

FIG. 3 illustrates relationships between a concentration of dopants and resistance values for various types of semiconductors.

In FIG. 3, the relationships between the concentration of dopants and the resistance values are illustrated for n-type GaP, p-type GaP, n-type GaAs, p-type GaAs, n-type Ge, and p-type Ge.

As illustrated in FIG. 3, as the concentration of dopant in the semiconductor increases, the resistance value of the semiconductor layer decreases. This relationship is virtually inversely proportional in the logarithmic values. In other words, the higher the impurity concentration in the semiconductor the lower the resistance value of the semiconductor layer, so the current can spread over a wider area.

Also, a higher impurity concentration in the semiconductor layer is preferable from the point of view of forming ohmic contact between the semiconductor layer and the metal layer. When the impurity concentration in the semiconductor layer is higher, a width of a depletion layer between the semiconductor and the metal becomes narrower. Thereby, a thickness of an energy barrier can be reduced, and electrons can more easily move between the semiconductor and the metal by a tunnel effect. Therefore, it is possible to obtain good ohmic contact.

However, if the impurity concentration is extremely high, light absorption occurs within the semiconductor layer due to free carriers. In other words, the light emitted by the light emitting layer 53 is absorbed by the semiconductor layer (i.e., the second semiconductor layer 52), resulting in the brightness decreasing. The light absorption by the free carriers increases as the impurity concentration increases. In other words, as the doping concentration increases the light absorption coefficient increases. Also, when the impurity concentration becomes higher, a crystal quality of the semiconductor layer may be lowered, resulting in a poor smoothness of the crystal surface.

The impurity concentration of the first portion 520 of the second semiconductor layer 52 was investigated from the points of view of resistance value, absorption of light, and ohmic contact in the first portion 520 of the second semiconductor layer 52, corresponding to the impurity concentration. As a result, it was determined to be preferable that the impurity concentration in the first portion 520 of the second semiconductor layer 52 is more than or equal to 1×10¹⁹ cm⁻³ and less than or equal to 1×10²¹ cm⁻³.

By satisfying the concentration range mentioned above, it may be possible to achieve higher brightness, even when the opening portions 21 of the first electrode layer 20 have relatively large equivalent circle diameters that can be formed by photolithography or the like, for example. Furthermore, in the semiconductor light emitting device 110, even in a device with a large chip size, reduction of brightness due to concentration of current is suppressed, so a great improvement in the properties are achieved.

The dopant used for doping on the second semiconductor layer 52 is selected based on a conductivity type of the second semiconductor layer 52. For example, in a case of p-type conductivity, it may be preferable for the semiconductor layer 52 to include one selected from the group of C, Ca, Mg, Mn, and Zn. Also, in a case of n-type conductivity, it may be preferable to include one from the group of Ge, Se, S, Sn, Si, and Te.

In the semiconductor light emitting device 110, higher heat dissipation can be obtained by providing a relatively larger first electrode layer 20, so a temperature rise of the semiconductor light emitting device 110 is suppressed. Also, the temperature rise of the semiconductor light emitting device 110 is suppressed by adjusting the size (for example the equivalent circle diameter) of the opening portions 21 provided in the first electrode layer 20. In other words, the series resistance may be reduced by lowering the forward voltage of the semiconductor light emitting device 110, so the heat generation itself can be reduced.

To realize this effect, the current may flow from the first electrode layer 20 with the opening portions 21 uniformly over the whole face of the second semiconductor layer 52. Whereby the current flows uniformly to the second semiconductor layer 52, the size of the opening portions 21 and the distance between the centers of the opening portions 21 are limited to certain extents.

If the impurity concentration of the first portion 520 of the second semiconductor layer 52 through which the current flows is in the concentration range (1) mentioned above, the extent over which the current flows as obtained by calculation such as simulation or the like is up to about 25 μm from the edges of the first electrode layer 20. In other words, if the equivalent circle diameter of the opening portions 21 is more than or equal to 50 μm, an area over which the current does not flow is produced, and it is not possible to reduce the series resistance, and it is not possible to reduce the voltage in the forward direction. Therefore the upper bound of the equivalent circle diameter of the opening portions 21 is preferably less than or equal to 50 μm.

On the other hand, although there is no limitation on the lower bound of the equivalent circle diameter of the opening portions 21 from the viewpoint of resistance value or current spread, for ease of manufacture the lower bound may be more than or equal to 10 nm, and preferably more than or equal to 30 nm.

If a resist pattern is produced using photolithography for forming the opening portions 21, the resist pattern will be difficult to produce if the opening portion pattern is too small. Furthermore, if there are unevenness or warps on the substrate on which the resist pattern is formed, forming a fine pattern will be more difficult. Therefore, in the case that the opening portions 21 are formed using photolithography, a lower bound on the equivalent circle diameter of the opening portions 21 may be about 1 μm.

Therefore, the equivalent circle diameters of the opening portions 21 of the first electrode layer 20 are preferably more than or equal to 10 nm and less than or equal to 50 μm. Also, more preferably the range is more than or equal to 30 nm and less than or equal to 50 μm. The preferred range when the opening portions 21 are formed using photolithography is more than or equal to 1 μm and less than or equal to 50 μm.

Furthermore, the material of the metal portion 23 of the first electrode layer 20 preferably contains, for example, Ag or Au as the base metal. Thereby, it is possible to suppress absorption losses of the light emitted from the light emitting layer 53. Further, the material of the metal portion 23 preferably contains at least one material selected from the group Al, Zn, Zr, Si, Ge, Pt, Rh, Ni, Pd, Cu, Sn, C, Mg, Cr, Te, Se, and Ti, or an alloy made of at least two materials selected therefrom. Thereby, the ohmic properties, the adhesiveness, and heat resistance properties are improved. Preferably the metal used as the material of the metal portion 23 has sufficient electrical conductivity and thermal conductivity. However, the embodiment is not limited to these, and any metal can be used.

For example, the first electrode layer 20 between arbitrary two points in the metal portion 23 (in the part where the opening portions 21 are not provided) are continuous without discontinuity from the current supply sources such as the pad electrode and so on. Hence, it is possible to maintain a low resistance value and ensure electrical continuity.

Also, if a plurality of current supply sources are provided, each current supply source may be continuously connected with its corresponding metal portion 23 of the first electrode layer 20.

Also, the sheet resistance of the first electrode layer 20 is preferably 10 Ω/square or less, and more preferably 5 Ω/square or less. The smaller the sheet resistance, the smaller the heat generated in the semiconductor light emitting device 110, and the more uniform light generation can be obtained, and the increase in brightness is more distinct.

For example, in a semiconductor light emitting device 110 that emits red light, the second semiconductor layer 52 may include compound semiconductors such as GaAs, GaP, or the like. After forming a stacked structure of Au and Au—Zn alloy on the second semiconductor layer 52, an interface between the metal and the semiconductor layer may be annealed and contain Zn diffused from Au—Zn alloy. Since Zn is the p-type dopant for the second semiconductor layer 52, the metal and the semiconductor layer may be brought into ohmic contact.

In the semiconductor light emitting device 110 according to the embodiment, the metal layer of the stacked structure is formed in the same way as described above, and the first electrode layer 20 is formed by forming the opening portions 21 by a method that is described later. Here, if the thickness of the first electrode layer 20 is too thin, the amount of dopant is too small, and doping is insufficient. As a result sufficient ohmic contact cannot be obtained, and the resistance value may increase.

As a result of experimental investigations, it was determined that if the thickness of the first electrode layer 20 is more than or equal to 10 nm, it is possible to achieve sufficient ohmic contact. Also, if the thickness of the first electrode layer 20 is more than or equal to 30 nm, the ohmic contact is further improved. On the other hand, the greater the thickness of the first electrode layer 20 the lower the resistance value. Therefore, the thickness of the first electrode layer 20 is preferably less than or equal to 100 nm. More preferably, the thickness of the first electrode layer 20 is less than or equal to 50 nm from the viewpoint of ensuring the transmission of the light produced by the light emitting layer 53.

Here, a reflectance (bulk reflectance) in the first electrode layer 20 with respect to the light emitted from the light emitting layer 53 is preferably 70% or higher. This is because when the reflectance is low for metal reflections, the light is converted into heat which causes losses. Further, the light reflected by the first electrode layer 20 propagates toward the light emitting layer 53 and may be reused by using a reflection layer (not shown in the drawings) or the like provided below the light emitting layer 53. In other words, the light may propagate toward the first electrode layer 20 again and can be extracted. Thereby, the light emitted from the light emitting layer 53 passes through the first electrode layer 20.

As described above, in the semiconductor light emitting device 110 according to the embodiment, it is possible to improve the luminous efficiency of the light emitting layer 53 and improve the light extraction efficiency from the first electrode layer 20.

The following is an explanation of a method for manufacturing a semiconductor light emitting device.

FIG. 4 is a flowchart illustrating the method of manufacturing a semiconductor light emitting device.

Namely, the method for manufacturing the semiconductor light emitting device includes processes of: forming a structural body by forming the first semiconductor layer 51, forming the light emitting layer 53 on the first semiconductor layer 51, and forming the second semiconductor layer 52 on the light emitting layer 53 (Step S10); forming a metal layer on the second semiconductor layer 52 (Step S20); forming a mask pattern on the metal layer (Step S30); forming an electrode layer (first electrode layer 20) having a plurality of opening portions 21 by etching the metal layer using the mask pattern as the mask (Step S40).

In the process of forming the mask pattern (Step S30), the mask pattern may be formed by using one of the following methods from (A) to (D), for example.

### (A) Method Using Photolithography

In this manufacturing method, first, a resist layer is formed on the metal layer. Next, the resist layer is irradiated with an exposure light, developed, and the resist pattern having the resist openings is formed. This resist pattern is the mask pattern.

(B) Method Using a Stamper having Protrusions

In this method, first, a resist layer is formed on the metal layer. Next, protrusions of the stamper are pressed into the resist layer, to form the resist pattern having the plurality of resist depressions on the resist layer. Then the resist pattern is etched, bottoms of the resist depressions are removed, and the resist openings are formed. This resist pattern with the resist openings is used as the mask pattern.

### (C) Method Using the Self-Assembly of Block Copolymers

In this method, a composition that contains a block copolymer is applied to a surface of at least a part of the metal layer. Next, phase separation of the block copolymer is carried out to generate a microdomain pattern. This microdomain pattern is the mask pattern.

### (D) Method Using a Mask Formed of Fine-Particles

In this method, first a resist layer is formed on the metal layer. Next, a single particle layer of the fine-particles is formed on the surface of the resist layer. Then, the resist layer is etched using the single particle layer as a mask.

Thereby, a resist pattern having a columnar configuration is obtained. Continuing, a solution of SOG (spin on glass) is coated onto the columnar resist pattern. Thereby, the resist pattern is buried in the SOG. Then, the SOG and the silica fine particles on the columnar resist pattern are removed by etching to form a structure of the columnar resist pattern and the SOG filled into the gaps. Then, the remaining resist pattern having the columnar configuration is etched. In this process, a mask pattern of the SOG is formed with a structure inverted from the columnar resist pattern.

The above manufacturing methods (A) through (D) are examples, and the embodiment is not limited to these.

Next, examples are described. The materials, values, manufacturing conditions, and so on indicated in the following description are examples and the manufacturing methods are not limited to these examples.

### FIRST EXAMPLE

In a first example, a semiconductor light emitting device 111 that emits red light is manufactured in accordance with the method of using photolithography as described in method (A) above.

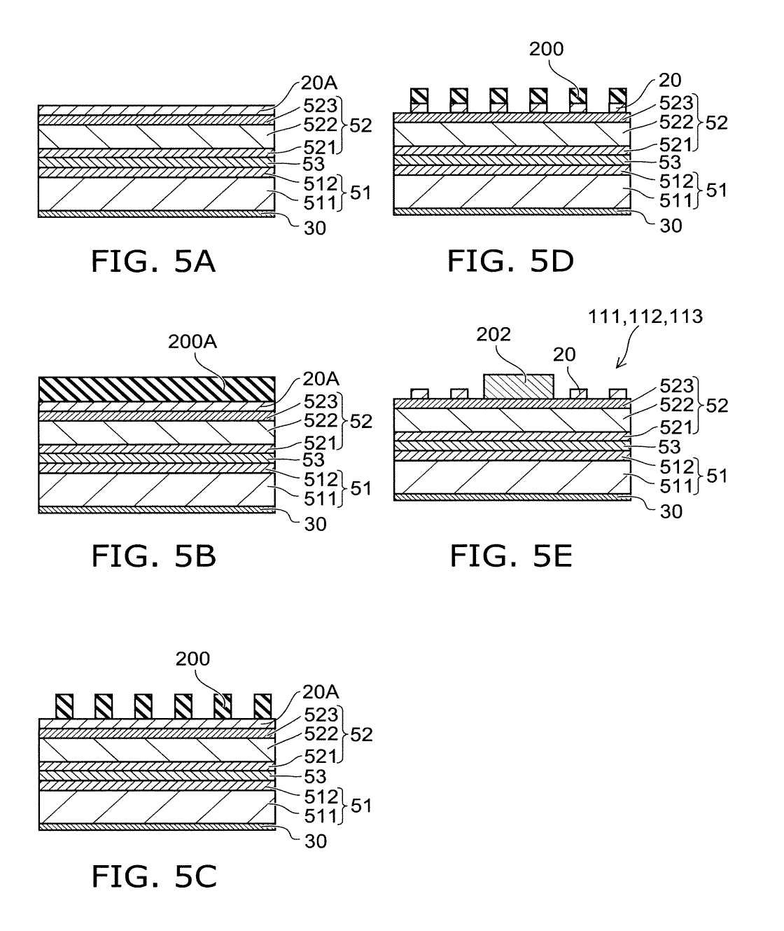

FIGS. 5A to 5E are schematic cross-sectional views illustrating a manufacturing method of the semiconductor light emitting device according to the first embodiment.

First, as illustrated in FIG. 5A, a heterostructure that includes an n-type InAlP clad layer 512, an InGaAlP light emitting layer 53, a p-type InAlP clad layer 521, and so on, is formed on the n-type GaAs substrate 511. Next, after epitaxially growing the p-type GaP current diffusion layer 522 on the heterostructure, the p-type GaP contact layer 523 doped with C is epitaxially grown on the current diffusion layer 522. At this time, an impurity concentration in the contact layer 523 is 5.0×10²⁰ cm⁻³.

Next, an Au—Ge alloy film with a film thickness of, for example, 150 nm is formed on the reverse side of the substrate 511. The Au—Ge alloy film is formed by a vacuum evaporation method, for example. Thereby, the second electrode layer 30 is formed.

Next, a metal layer 20A is formed on the contact layer 523 by, for example, a vacuum evaporation method. The metal layer 20A includes, for example, Au with a thickness of 10 nm and Au—Zn alloy (Zn content 3%) formed to a thickness of 30 nm, for example. Then, annealing is carried out in a nitrogen atmosphere for 30 minutes at 450° C., to obtain ohmic contact between the metal layer 20A and the contact layer 523, and between the second electrode layer 30 and the substrate 511.

Next, as illustrated in FIG. 5B, a layer (resist layer 200A) of an i-ray positive thermosetting resist (THMR IP3250 (trade name), manufactured by Tokyo Ohka Kogyo Co., Ltd.) with a thickness of 1000 nm is formed on the metal layer 20A, for example. Then, as illustrated in FIG. 5C, a resist pattern 200 having an opening portion diameter of 30 μm and a distance of 50 μm between the centers of the opening portions is formed using a photolithography apparatus. The area of the resist openings 202a as a percentage of the area of the resist layer 200A viewed from the Z-axis direction is about 30%.

Next, the metal layer 20A is etched for 90 seconds using an ion milling apparatus under the conditions of 500 volt (V) acceleration voltage and 40 milliampere (mA) ion current, to form openings corresponding to the opening portions 21. Thereby, the first electrode layer 20 with openings corresponding to the opening portions 21 is formed, as illustrated in FIG. 5D.

In the finally formed opening portions 21 that are formed, the equivalent circle diameter is 27 μm, the average distance between adjacent opening portions 21 is 48 μm, and the area of the opening portions as a percentage of the area of the first electrode layer 20 (opening portion area ratio) when viewed from the Z-axis direction is 30%.

After etching the metal layer 20A, oxygen ashing is carried out to remove the residual resist pattern 200. Finally, as illustrated in FIG. 5E, the pad electrode 202 made from Au, for example, is formed on a portion of the first electrode layer 20. The shape of the pad electrode 202 when viewed from the Z-axis direction is circular, for example. If necessary, a fine wire electrode (not shown in the drawings) is provided on the pad electrode 202. Thereby, the semiconductor light emitting device 111 is completed.

In this example, the contact layer 523 is doped with C to reduce the resistance value of the contact layer 523, but besides C, doping with at least one of Mg, Mn, or Zn may be used to reduce the resistance value.

### SECOND EXAMPLE

In a second example, a semiconductor light emitting device 112 is manufactured in the same way as the first example, having the first electrode layer 20 with the plurality of opening portions 21 formed by using photolithography. In the semiconductor light emitting device 112, the equivalent circle diameter of the opening portions 21 is 11 μm, the average distance between opening portions is 19 μm, and the opening portion area ratio is 28%.

### THIRD EXAMPLE

In a third example, a semiconductor light emitting device 113 is manufactured in the same way as the first example, having the first electrode layer 20 with the plurality of opening portions 21 formed by using photolithography. In the semiconductor light emitting device 113, the equivalent circle diameter of the opening portions 21 is 4 μm, the average distance between opening portions is 10 μm, and the opening portion area ratio is 24%.

### FOURTH EXAMPLE

In a fourth example, the semiconductor light emitting device 114 that emits red light is manufactured according to the method of using the self-assembly of block copolymers as described in (C) above.

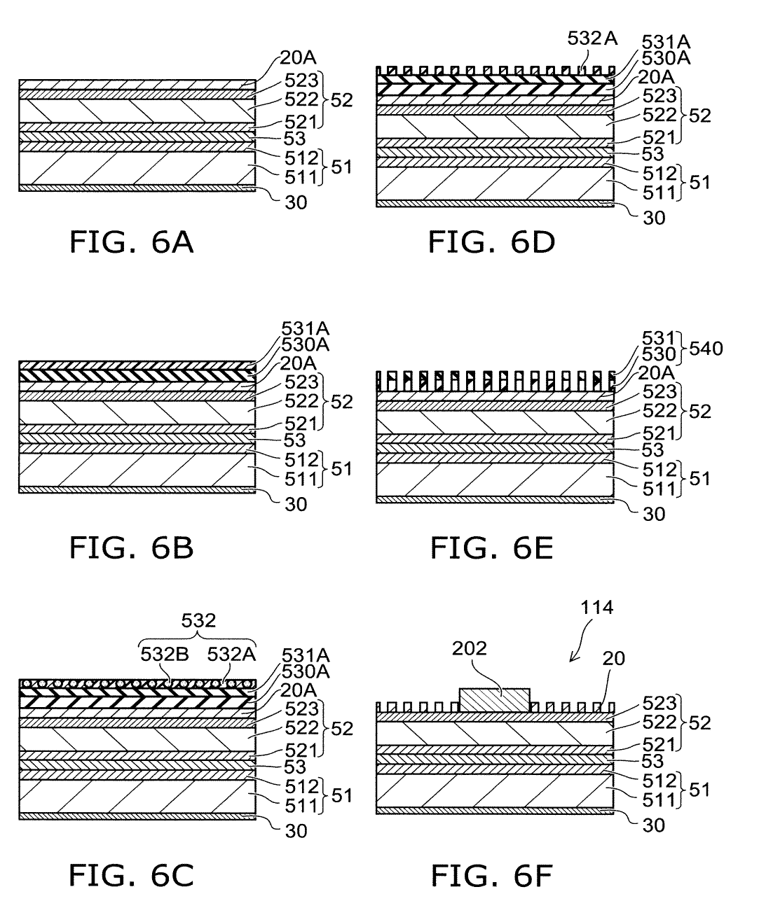

FIGS. 6A to 6F are schematic cross-sectional views illustrating the manufacturing method of the semiconductor light emitting device according to the fourth example.

First, as illustrated in FIG. 6A, a heterostructure that includes the n-type InAlP clad layer 512, the InGaAlP light emitting layer 53, the p-type InAlP clad layer 521, and so on, is formed on the n-type GaAs substrate 511, the same as for the first example.

Then, after epitaxially growing the p-type GaP current diffusion layer 522 on the heterostructure, the p-type GaP contact layer 523 doped with C is epitaxially grown on the current diffusion layer 522. At this time, the impurity concentration in the contact layer 523 is 5.0×10²⁰ cm⁻³.

Next, an Au—Ge alloy film with a film thickness of, for example, 150 nm is formed on the reverse side of the substrate 511. The Au—Ge alloy film is formed by a vacuum evaporation method, for example. Thereby, the second electrode layer 30 is formed.

Next, the metal layer 20A is formed on the contact layer 523 by, for example, by the vacuum evaporation method. The metal layer 20A includes, for example, Au with a thickness of 10 nm and, for example, Au—Zn alloy (Zn content 3%) formed to a thickness of 30 nm. Then, annealing is carried out in a nitrogen atmosphere for 30 minutes at 450° C., to obtain ohmic contact between the metal layer 20A and the contact layer 523, and between the metal layer 30 and the substrate 511. Next, as illustrated in FIG. 6B, a solution of i-ray positive thermosetting resist (THMR IP3250 (trade name), manufactured by Tokyo Ohka Kogyo Co., Ltd.) diluted in ethyl lactate is spin coated on the metal layer 20A. The dilution rate is 1:1 by weight, for example. Then the work piece is heated for 90 seconds on a hot plate at a temperature of 110° C. Then heating is carried out for one hour in a nitrogen atmosphere within an antioxidation oven at 250° C. to induce a thermosetting reaction. Thereby, the resist layer 530A is obtained. The film thickness of the resist layer 530A is about 170 nm.

Next, a solution for spin on glass (SOG) (OCD-5500T (trade name), manufactured by Tokyo Ohka Kogyo Co., Ltd.) diluted with ethyl lactate is spin coated on the resist layer 530A. The dilution rate is, for example, 1 part by weight SOG solution to 3 parts by weight ethyl lactate. Then the work piece is heated for 90 seconds on a hot plate at a temperature of 110° C. Then heating is carried out for one hour in a nitrogen atmosphere within an antioxidation oven at 250° C. Thereby, an SOG layer 531A is formed. The thickness of the SOG layer 531A is 30 nm, for example.

Next, a solution of PS-PMMA diblock copolymer (P6001 (trade name), PS molecular weight 166,000, PMMA molecular weight 42,000, manufactured by Polymer Source, Inc.) and a solution of PS homopolymer (molecular weight 2000) are prepared.

Each solution is about 2 wt % in propylene glycol monomethylether acetate (PGMEA) solvent.

Then the PS-PMMA diblock copolymer solution and the PS homopolymer solution are mixed in the proportions 8:2 by weight, to prepare a resin composition that includes block copolymer.

Next, as illustrated in FIG. 6C, a block copolymer layer is formed by applying the prepared resin composition solution on the SOG layer 531A by spin coating at 2500 rpm, for example. Then the work piece is heated for 90 seconds on a hot plate at a temperature of 110° C. Then heating is carried out for eight hours in a nitrogen atmosphere within an antioxidation oven at 180° C. Thereby, the diblock copolymer is phase separated, and a morphology (diblock copolymer layer 532) is obtained wherein dot shaped microdomains 532B of PMMA are formed within the PS matrix 532A.

Next, by carrying out a reactive ion etching (RIE) process (O₂ flow rate 5 sccm, Ar flow rate 25 sccm, pressure 13.3 Pa, RF power 100 W) on the block copolymer layer 532, the dot shaped microdomains 532B of PMMA in the block copolymer are selectively removed. Thereby, the PS matrix 532A remains, as illustrated in FIG. 6D.

Next, as illustrated in FIG. 6E, the SOG layer 531A is etched using the remaining PS matrix 532A as a mask. An RIE process is used for the etching, using a mixed gas of, for example, CF₄ and CHF₃. Here, the RIE conditions are, for example, CF₄ flow rate 10 sccm, CHF₃ flow rate 20 sccm, pressure 0.7 Pa, and RF power 100 W. Thereby, the SOG mesh pattern 531 is formed.

Furthermore, a resist layer 530A base material is etched using an RIE process using oxygen (O₂ flow rate 30 sccm, pressure 0.3 Pa, 100 W), to form a resist mesh pattern 530. A stacked body of the resist mesh pattern 530 and the SOG mesh pattern 531 constitute a SOG/resist mesh pattern 540.

Next, the lower metal layer 20A is milled to form openings corresponding to the opening portions 21 using the formed SOG/resist mesh pattern 540 as a mask, in the same way as the first example. Thereby, as illustrated in FIG. 6F, the first electrode layer 20 with the openings corresponding to the opening portions 21 is formed.

In the finally formed opening portions 21 that are formed, the equivalent circle diameter is 15 nm, the average distance between adjacent opening portions 21 is 60 nm, and the opening portion area ratio is 13%.

Next, the remaining SOG mesh pattern 531 is removed using a dilute hydrofluoric acid (5 wt %) process. In addition the resist mesh pattern 530 is removed by an ashing process. Finally, the pad electrode 202 made from Au, for example, is formed on a portion of the first electrode layer 20. The shape of the pad electrode 202 when viewed from the Z-axis direction is circular, for example. If necessary, a fine wire electrode (not shown on the drawings) is provided in the pad electrode 202. Thereby, the semiconductor light emitting device 114 is completed.

### FIFTH EXAMPLE

In a fifth example, the semiconductor light emitting device 115 is manufactured using the method of using the self-assembly of block copolymers in the same way as the fourth example.

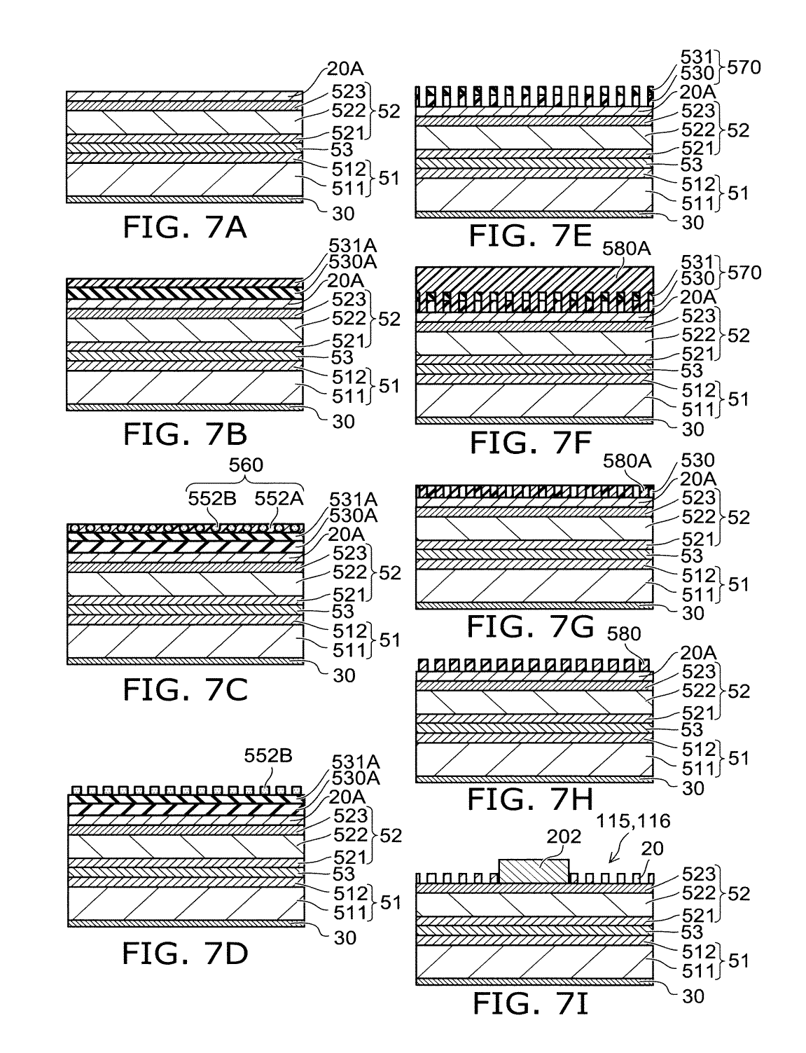

FIGS. 7A to 7I are schematic cross-sectional views illustrating the manufacturing method of the semiconductor light emitting device according to the fifth example.

A phase separation pattern of the block copolymer used in the fifth example includes PS dot portions and a PMMA matrix portion.

First, as illustrated in FIG. 7A, a heterostructure that includes the n-type InAlP clad layer 512, the InGaAlP light emitting layer 53, the p-type InAlP clad layer 521, and so on, is formed on the n-type GaAs substrate 511, the same as for the first example. Then, after epitaxially growing the p-type GaP current diffusion layer 522 on the heterostructure, the p-type GaP contact layer 523 doped with C is epitaxially grown on the current diffusion layer 522. At this time the impurity concentration in the contact layer 523 is 5.0×10²⁰ cm⁻³.

Next, an Au—Ge alloy film with a film thickness of, for example, 150 nm is formed on the reverse side of the substrate 511. The Au—Ge alloy film is formed by a vacuum evaporation method, for example. Thereby, the second electrode layer 30 is formed.

Next, the metal layer 20A is formed on the contact layer 523 by, for example, the vacuum evaporation method. The metal layer 20A includes, for example, Au with a thickness of 10 nm and, for example, Au—Zn alloy (Zn content 3%) formed to a thickness of 30 nm. Then, annealing is carried out in a nitrogen atmosphere for 30 minutes at 450° C., to obtain ohmic contact between the metal layer 20A and the contact layer 523, and between the metal layer 30 and the substrate 511.

Next, as illustrated in FIG. 7B, a solution of i-ray positive thermosetting resist (THMR IP3250 (trade name), manufactured by Tokyo Ohka Kogyo Co., Ltd.) diluted in ethyl lactate is spin coated on the metal layer 20A. The dilution rate is 1:1 by weight, for example. Then the work piece is heated for 90 seconds on a hot plate at a temperature of 110° C. Then heating is carried out for one hour in a nitrogen atmosphere within an antioxidation oven at 250° C. to induce the thermosetting reaction. Thereby, the resist layer 530A is obtained. The film thickness of the resist layer 530A is about 170 nm.

Next, a SOG solution (OCD-5500T (trade name), manufactured by Tokyo Ohka Kogyo Co., Ltd.) diluted with ethyl lactate is spin coated on the resist layer 530A. The dilution rate is, for example, 1 part SOG solution to 3 parts ethyl lactate. Then the work piece is heated for 90 seconds on a hot plate at a temperature of 110° C. Then heating is carried out for one hour in a nitrogen atmosphere within an antioxidation oven at 250° C. Thereby, the SOG layer 531A is formed. The thickness of the SOG layer 531A is 30 nm, for example.

Next, a solution of PS-PMMA diblock copolymer (P2885 (trade name), PS molecular weight 315,000, PMMA molecular weight 815,000, manufactured by Polymer Source, Inc.), a solution of PS homopolymer (molecular weight 2000), and a solution of PMMA homopolymer (molecular weight 1700) are prepared.

Each solution is about 3.5 wt % in propylene glycol monomethylether acetate (PGMEA) solvent, for example.

Then the PS-PMMA diblock copolymer solution, the PS homopolymer solution, and the PMMA homopolymer solution are mixed in the proportions 8:2:1.5 by weight, to prepare a resin composition that includes block copolymer.

Next, as illustrated in FIG. 7C, a block copolymer layer is formed by applying the prepared resin composition solution on the SOG layer 531A by spin coating at 2000 rpm, for example. Then the work piece is heated for 90 seconds on a hot plate at a temperature of 110° C. Then heating is carried out for eight hours in a nitrogen atmosphere within an antioxidation oven at 230° C. Thereby, the diblock copolymer is phase separated, and a morphology (diblock copolymer layer 560) is obtained wherein dot shaped microdomains 552B of PS are formed within a PMMA matrix 552A.

Next, an RIE process is carried out on the diblock copolymer layer 560, the same as for the fourth example. Thereby, the block copolymer PMMA matrix 552A is selectively removed. Thereby, the microdomains 552B remain, as illustrated in FIG. 7D.

Next, an RIE process is carried out on the SOG layer 510A using the remaining PS microdomains 552B as a mask, the same as for the second example. In addition, the substrate resist layer 530A is etched using an RIE process using oxygen. Thereby, SOG/resist pillars 570 are formed, as illustrated in FIG. 7E.

Next, as illustrated in FIG. 7F, an SOG solution (OCD-12000T (trade name), manufactured by Tokyo Ohka Kogyo Co., Ltd.) is applied to the SOG/Resist pillars 570, and pre-baking is carried out on a hot plate for 90 seconds at 110° C. Thereby, the SOG/resist pillars 570 are embedded in the SOG layer 580A.

Next, as illustrated in FIG. 7G, etching is carried out until the resist layer 530 of the pillars 570 are exposed, by carrying out an RIE process using a mixed gas of CF₄ and CHF₃ (CF₄ flow rate 10 sccm, CHF₃ flow rate 20 sccm, pressure 0.7 Pa, RF power 100 W).

In addition, the SOG mesh pattern 580 as illustrated in FIG. 7H is obtained by selectively removing the resist layer 530A only and leaving the SOG layer 580A, using an ashing process.

Next, the lower metal layer 20A is milled to form openings corresponding to the opening portions 21 using the formed SOG/resist mesh pattern 580 as a mask, the same as for the first example. Thereby, the first electrode layer 20 with the openings corresponding to the opening portions 21 is formed, as illustrated in FIG. 7I.

In the finally formed opening portions 21 that were formed, the equivalent circle diameter is 145 nm, the average distance between adjacent opening portions 21 is 352 nm, and the opening portion area ratio is 20%.

Next, the remaining SOG mesh pattern 580 is removed using a dilute hydrofluoric acid (5 wt %) process. Finally, the pad electrode 202 made from Au, for example, is formed on a portion of the first electrode layer 20. The shape of the pad electrode 202 when viewed from the Z-axis direction is circular, for example. If necessary, a fine wire electrode (not shown on the drawings) is provided in the pad electrode 202. Thereby, the semiconductor light emitting device 115 is completed.

### SIXTH EXAMPLE

In a sixth example, a semiconductor light emitting device 116 is manufactured similar to the fifth example, having the first electrode layer 20 with the plurality of opening portions 21. In this case, a mixture of the block copolymer solution, the PS homopolymer solution, and the PMMA homopolymer solution in a proportion of 6:4:3 by weight is used as the resin composition solution containing the block copolymer.

In the semiconductor light emitting device 116, in the opening portions 21 that are formed, the equivalent circle diameter is 317 nm, the average distance between opening portions is 657 nm, and the opening portion area ratio is 27%.

### FIRST COMPARATIVE EXAMPLE

For comparison, a semiconductor light emitting device 191 is manufactured wherein a circular pad electrode only is formed on the p-type GaP contact layer 523 doped with C.

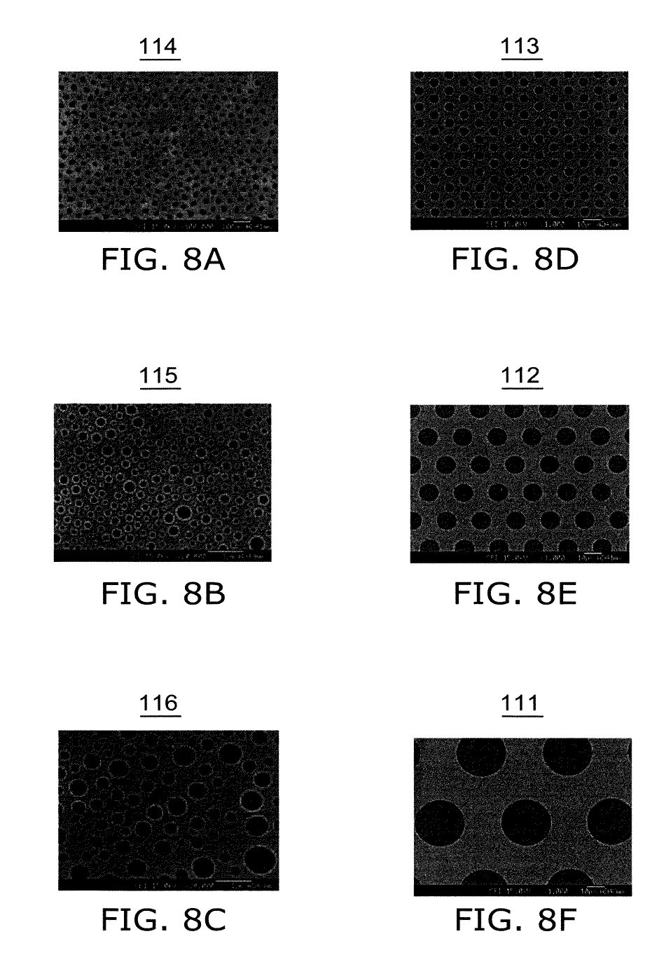

FIGS. 8A to 8F illustrate examples of electron microscope photographs of the first electrode layer of the semiconductor light emitting devices.

FIG. 8A illustrates the semiconductor light emitting device 114 (fourth example), FIG. 8B illustrates 115 (fifth example), FIG. 8C illustrates 116 (sixth example), FIG. 8D illustrates 113 (third example), FIG. 8E illustrates 112 (second example), and FIG. 8F illustrates 111 (first example). In each case the first electrode layer is illustrated.

The semiconductor light emitting devices 111, 112, 113, 114, 115, 116, and 191 (comparative example) are each made square with a length of 900 μm square by dicing. The comparison of the properties of each of the semiconductor light emitting devices is carried out for bare chips.

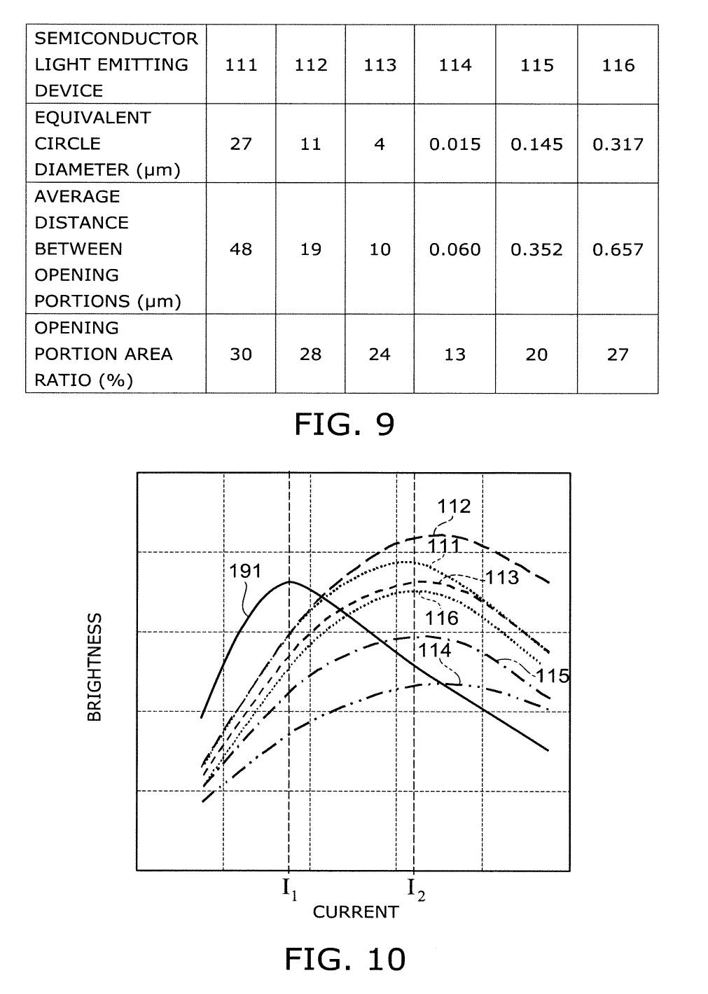

FIG. 9 illustrates the equivalent circle diameter, average distance between opening portions, and the opening portion area ratio for the semiconductor light emitting devices according to each example.

FIG. 10 is a graph illustrating examples of the properties of the examples and the comparative examples.

In FIG. 10, the horizontal axis is the current, and the vertical axis is the output.

In the semiconductor light emitting devices 111, 112, 113, 114, 115, and 116, in the low current region the output value is lower than the semiconductor light emitting device 191 at the same current value.

However, when the current is increased and exceeds the current value I₁, the output of semiconductor light emitting device 191 reduces. This is because the brightness is reduced by the reduction in the light emitting area due to current concentration, and generation of heat.

In contrast, in semiconductor light emitting devices 111, 112, 113, 114, 115, and 116, when the current value I₁ is exceeded and until the current value I₂ is reached, there is no reduction in output.

This is because by providing the first electrode layer 20 over a wide area on the second semiconductor layer 52, the heat dissipation of the semiconductor light emitting device is improved, and current concentration is reduced.

Also, it can be seen that the higher the area ratio of the opening portions 21 in the semiconductor light emitting device, the higher the brightness at the current value I₂. This is because the higher the opening portion area ratio, the higher the transmissivity of the first electrode layer 20 itself, so more light is extracted.

However, when the semiconductor light emitting device 111 and semiconductor light emitting device 112 are compared, the brightness of the semiconductor light emitting device 111 is lower than that of the semiconductor light emitting device 112, even though the opening portion area ratio is higher. This is because the opening portions 21 of the semiconductor light emitting device 111 are larger than the spread of the current from the first electrode layer 20, so it is not possible to obtain sufficiently uniform light emission over the whole opening portion. However, when compared with the semiconductor light emitting device 191, the semiconductor light emitting device 111 achieves higher brightness in the high current area.

Also, as a result of measuring the current—voltage characteristics for the semiconductor light emitting devices 111, 112, 113, 114, 115, 116, and 191, it was found that the Vf values of the semiconductor light emitting devices 111, 112, 113, 114, 115, and 116 were lower than that of the semiconductor light emitting device 191. This is because the first electrode layer 20 is provided over a wide area on the second semiconductor layer 52, as stated previously, so the heat dissipation is improved.

The semiconductor light emitting devices 111, 112, 113, 114, 115, and 116 are particularly effective when using a light emitting layer 53 that emits red light (wavelength 610 nm to 640 nm) Ag and Au, which are used as the material in the first electrode layer 20, do not easily absorb red light. Also, in the semiconductor light emitting devices 111, 112, 113, 114, 115, and 116 which include the first portion 520 with the above impurity concentration, the light emitting layer 53 can emit sufficient red light. Therefore, the light emitted from the light emitting layer 53 can be efficiently extracted.

From the above it can be seen that the semiconductor light emitting devices 111, 112, 113, 114, 115, and 116 have extremely good light emission characteristics from the low current region to the high current region. These types of light emission characteristics are particularly advantageous in chips with a large construction such as 1 mm square, in other words with an external area of the first electrode layer 20 of 1 mm² or larger, and when a high current is flowing.

Also, the effect of improvement in the properties of the semiconductor light emitting devices 111, 112, 113, 114, 115, and 116 is significant when the current is 100 mA or higher, although this depends on the area of the first electrode layer 20.

### SEVENTH EXAMPLE

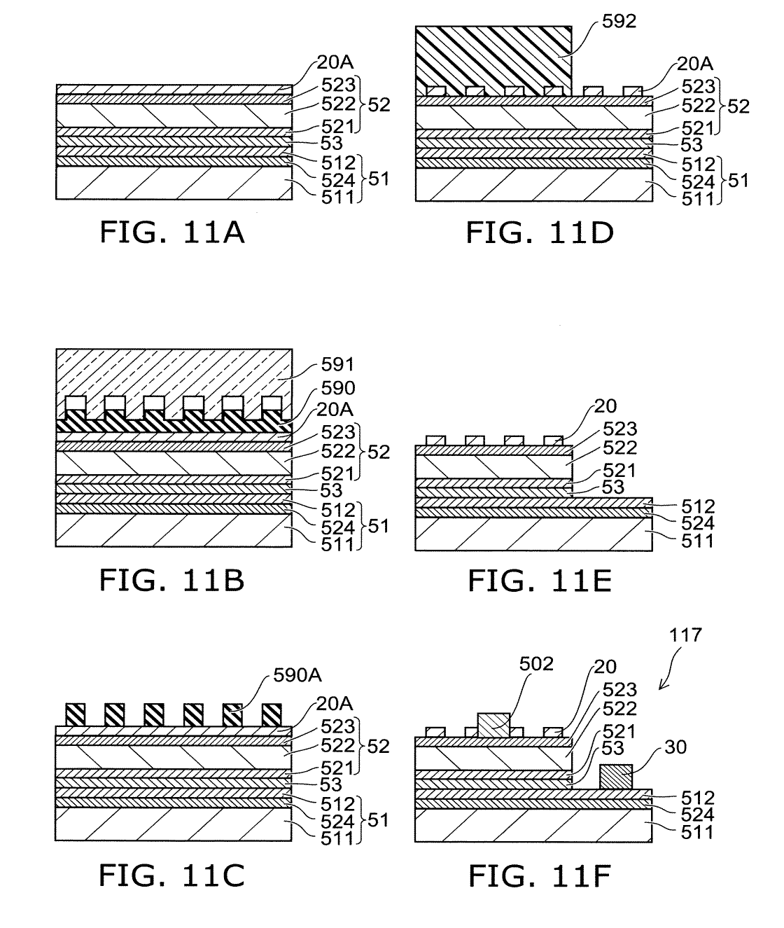

FIG. 11 is a schematic cross-sectional view explaining a manufacturing method of a semiconductor light emitting device according to a seventh example.

In the seventh example, a semiconductor light emitting device 117 according to the first embodiment is manufactured in accordance with the method of using a stamper as described in (B) above. The wavelength of the light emitted from this semiconductor light emitting device 117 is 440 nm. In the semiconductor light emitting device 117 according to example 7, the material and construction of the semiconductor multi-layer film are different from the semiconductor light emitting devices according to examples 1 through 6, and the second electrode layer 30 is provided on the top side, the same as the first electrode layer 20.

First, as illustrated in FIG. 11A, an n-type GaN buffer layer 524, for example, is formed on a substrate 511 made from sapphire, for example. Next, the first semiconductor layer 51, the second semiconductor layer 52, and the light emitting layer 53 are formed on the buffer layer 524, by, for example, forming films in the sequence n-type GaN clad layer 512, the light emitting layer 53 that includes an MQW configuration using InGaN and GaN, the p-type AlGaN clad layer 521, the p-type GaN current diffusion layer 522, and the p-type GaN contact layer 523 doped with Mg (impurity concentration 5.0×10¹⁹ cm⁻³).

Next, the metal layer 20A is formed on the contact layer 523 by, for example, the vacuum evaporation method. The metal layer 20A includes, for example, 5 nm thickness Ni and 30 nm thickness Ag.

Next, a solution of an i-ray positive thermosetting resist is applied to the metal layer 20A. This solution is i-line positive thermal hardening resist (THMR IP3250 (trade name), manufactured by Tokyo Ohka Kogyo Co., Ltd.) diluted 1:1 in ethyl lactate. The solution is applied by spin coating at 3000 rpm. Then, the solution is heated on a hot plate. The heating conditions were 110° C. for 90 seconds. Thereby, the thermosetting of the resist solution is caused. The film thickness of the resist layer 590 is about 170 nm.

Next, a mold, which is a quartz stamper 591, as illustrated in FIG. 11B, is prepared. An uneven pattern of the stamper 591 is formed by, for example, an electron beam lithography patterning. The uneven pattern is an array of pillars 120 nm high, 60 nm diameter, at 100 nm periodic spacing at the densest arrangement. At this time, a fluorine based separation agent such as perfluoropolyether or the like may be coated on the surface of the stamper 591 to reduce the surface energy of the stamper 591. As a result of this coating process the separating properties of the stamper 591 are improved.

Next, as illustrated in FIG. 11B, the uenven pattern the stamper 591 is pressed into the resist layer 590. The stamper 591 is pressed into the resist layer 590 using, for example, a heater plate press (model N4005-00 (trade name), manufactured by NPA). The press conditions are heating temperature 128° C., pressure 60 kN, and pressing time one hour. Then the stamper 591 is cooled to room temperature and removed vertically. Thereby, a pattern that is a reverse of the pattern of irregularities of the stamper 591 is formed on the resist layer 590. As illustrated in FIG. 11C, the reverse pattern is the mesh pattern 590A with a periodic array of opening portions.

Next, openings corresponding to the opening portions 21 are formed in the metal layer 20A by ion milling, is the same way as the first example. As illustrated in FIG. 11D, the metal layer 20A in which the openings corresponding to the opening portions 21 are formed becomes the first electrode layer 20. In this case the equivalent circle diameter of the finally formed opening portions 21 is 60 nm, and the average distance between opening portions is 100 nm.

Next, as illustrated in FIG. 11D, after forming a resist layer 592 on a portion of the face of the first electrode layer 20 by the lithography method, etching is carried out by ICP (Inductive Coupled Plasma)—RIE until the n-type GaN clad layer 512 is exposed. Then, as illustrated in FIG. 11E, the remaining resist layer 592 is removed by ashing.

Next, the second electrode layer 30 is formed on the exposed portion of the face of the n-type GaN clad layer 512. Also, the pad electrode 502 is formed on a portion of the face of the first electrode layer 20.

Finally, high speed high temperature annealing is carried out, to form ohmic contact between the electrode layers and the semiconductor layers. Thereby, as illustrated in FIG. 11F, the semiconductor light emitting device 117 according to example 7 is completed.

### SECOND COMPARATIVE EXAMPLE

For comparison, a semiconductor light emitting device 192 is manufactured wherein a circular pad electrode only is formed on the p-type GaN contact layer 523 doped with Mg, without forming the first electrode layer 20.

The semiconductor light emitting devices 117 and 192 are each formed square with a side of length 600 μm square by dicing. As a result of measuring the brightness characteristics and the current—voltage properties using a chip tester, in the semiconductor light emitting device 117 uniform light emission properties were seen in the high current region, the same as the results for the first example to the sixth example and the first example and the second example and the forward voltage was low.

The embodiments have been described above, but the invention is not limited to these examples. For example, similar to the first electrode layer 20, the plurality of opening portions 21 may be provided on the second electrode layer 30 provided on the front face or the reverse face of the structural body 100. Also, in the explanation the first conductivity type is n-type, and the second conductivity type is p-type, but first conductivity type may be p-type, and the second conductivity type may be n-type.

As explained above, with the semiconductor light emitting device and manufacturing method according to the embodiment, it is possible to increase the light emission efficiency (light extraction efficiency) while maintaining a uniform spread of current to the semiconductor layers by using the first electrode layer 20 having the opening portions 21.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor light emitting device, comprising:
a first semiconductor layer of a first conductivity type;
a first electrode layer including a metal portion having a plurality of opening portions, the plurality of opening portions penetrating the metal portion along a direction from the first semiconductor layer toward the first electrode layer, the plurality of opening portions having an equivalent circle diameter of a shape of the plurality of opening portions when viewed along the direction, the equivalent circle diameter being not less than 10 nanometers and not more than 50 micrometers;
a second semiconductor layer of a second conductivity type provided between the first semiconductor layer and the first electrode layer, the second semiconductor layer including a first portion in contact with the first electrode layer, the first portion having an impurity concentration of not less than 1×10¹⁹/cubic centimeter and not more than 1×10²¹/cubic centimeter;
a light emitting layer provided between the first semiconductor layer and the second semiconductor layer; and
a second electrode layer connected to the first semiconductor layer.

2. The device according to claim 1, wherein a thickness of the metal portion along the direction is not less than 10 nanometers and not more than 100 nanometers.

3. The device according to claim 1, wherein a thickness of the second semiconductor layer along the direction is not less than 10 nanometers and not more than 5 micrometer.

4. The device according to claim 1, wherein the metal portion contains at least one of Ag, Au, Al, Zn, Zr, Si, Ge, Pt, Rh, Ni, Pd, Cu, Sn, C, Mg, Cr, Te, Se, and Ti.

5. The device according to claim 1, wherein the second semiconductor layer contains at least one of C, Ca, Ge, Mg, Mn, Se, Si, Sn, Te, and Zn as a dopant.

6. The device according to claim 1, wherein the first portion is in ohmic contact with the first electrode layer.

7. The device according to claim 1, wherein the first portion includes a contact layer being in contact with the first electrode layer.

8. The device according to claim 1, wherein the first portion includes a contact layer being in contact with the first electrode layer and a current diffusion layer provided between the contact layer and the light emitting layer.

9. The device according to claim 1, wherein a sheet resistance value of the first portion is less than 10³ ohms/square.

10. The device according to claim 1, wherein a sheet resistance value of the first electrode layer is not more than 10 ohms/square.

11. The device according to claim 1, wherein the diameter of the equivalent circle shape is more than 1 micrometer and not more than 50 micrometers.

12. The device according to claim 1, wherein a heterostructure includes the first semiconductor layer, the light emitting layer and the second semiconductor layer.

13. The device according to claim 1, wherein the second semiconductor layer is provided between the first semiconductor layer and the first electrode layer.

14. The device according to claim 1, wherein the light emitting layer includes MQW (multiple quantum well) structure including barrier layers and well layers provided alternately.

15. The device according to claim 1, wherein the opening portions have a circular shape viewed along the direction.

16. The device according to claim 1, wherein the opening portions have a hexagonal shape viewed along the direction.

17. The device according to claim 1, wherein the plurality of the opening portions are arranged in a honeycomb manner.
